(19) United States
(12) Patent Application Publication
(10) Pub. No.: US 2026/0190699 A1
(43) Pub. Date: Jul. 2, 2026

(54) Light Emitting Display Apparatus

(71) Applicant: LG Display Co., Ltd., Seoul (KR)

(72) Inventor: JiYoung Ahn, Paju-si (KR)

(21) Appl. No.: 19/349,910

(22) Filed: Oct. 3, 2025

(30) Foreign Application Priority Data
Dec. 26, 2024 (KR) 10-2024-0197782

(51) Int. Cl. H10K 59/131; H10K 59/38

(52) U.S. Cl. CPC H10K 59/131; H10K 59/38

(57) ABSTRACT

A light emitting display apparatus may include a substrate including a plurality of subpixels having an emission area and a non-emission area, a data line and a gate line disposed in the non-emission area on the substrate, intersecting with each other, at least one insulating layer disposed on the data line and the gate line, and a color filter disposed on the at least one insulating layer, corresponding to at least one of the plurality of subpixels, one or more of the plurality of subpixels may include a low-reflectance pattern overlapping the emission area.

### CROSS-REFERENCE TO RELATED APPLICATION

This application claims the benefit of and priority to Republic of Korea Patent Application No. 10-2024-0197782 filed on Dec. 26, 2024, which is hereby incorporated by reference in its entirety.

### BACKGROUND

### Technical Field

The present disclosure relates to a light emitting display apparatus.

### Description of the Related Art

With the advancement of the information age, the demand for a display apparatus for displaying an image has increased in various forms. Therefore, various types of display apparatuses such as a liquid crystal display (LCD) apparatus, an organic light emitting display (OLED) apparatus, a micro light emitting diode (LED) display apparatus, and a quantum dot display (QD) apparatus have been recently used.

Among display apparatuses, the organic light emitting display apparatus is a self-luminance type. In the organic light emitting display apparatus, hole and electron are injected into an emission layer from an anode electrode for hole injection and a cathode electrode for electron injection, and the injected hole and electron are bonded to each other. Herein, when an exciton formed by the hole and the electron falls from the excited state to the ground state, the organic light emitting display apparatus may emit light and display an image.

Such the organic light emitting display apparatus has primarily employed a polarizer on a display surface of a panel to reduce external light reflection. However, when the organic light emitting display apparatus uses a polarizer, transmittance decreases, thereby reducing panel efficiency and increasing power consumption.

### SUMMARY

One or more embodiments of the present disclosure may provide a light emitting display apparatus capable of reducing reflectance and improving light efficiency in a pol-less structure that does not use a polarizer.

One or more embodiments of the present disclosure may provide a light emitting display apparatus capable of reducing reflectance, improving light efficiency, and enhancing display image quality by optimizing the cell reflectance of a light emitting portion to be suitable for the pol-less structure while maintaining the area of the light emitting portion.

Additional advantages and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

A light emitting display apparatus according to one or more embodiments of the present disclosure may include a substrate including a plurality of subpixels having an emission area and a non-emission area, a data line and a gate line disposed in the non-emission area on the substrate, intersecting with each other, at least one insulating layer disposed on the data line and the gate line, and a color filter disposed on the at least one insulating layer, corresponding to at least one of the plurality of subpixels, one or more of the plurality of subpixels may include a low-reflectance pattern overlapping the emission area.

According to one or more embodiments of the present disclosure, a light emitting display apparatus capable of reducing reflectance and improving light efficiency in a pol-less structure that does not use a polarizer may be provided.

According to one or more embodiments of the present disclosure, a light emitting display apparatus capable of reducing reflectance, improving light efficiency, and enhancing display image quality by optimizing the cell reflectance of a light emitting portion to be suitable for the pol-less structure while maintaining the area of the light emitting portion may be provided.

The light emitting display apparatus according to one or more embodiments of the present disclosure may optimize the cell reflectance while maintaining the area of a light emitting portion even in a pol less structure that does not use a polarizer. Through this, the light emitting display apparatus may reduce reflectance, improve light efficiency, and enhance display image quality. In addition, by unifying the material of the light emitting display apparatus, it is possible to reduce cost, decrease power consumption, and improve reliability and display quality, thereby reducing production energy and achieving environmental, social, and governance (ESG) benefits.

The effects of the present disclosure are not limited to the aforesaid, but other effects not described herein will be clearly understood by those skilled in the art from the following descriptions.

The details of the present disclosure described in technical problem, technical solution, and advantageous effects do not specify essential features of claims, and thus, the scope of claims is not limited by the details described in detailed description of the invention.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure, and together with the description serve to explain the principles and examples of the disclosure.

FIG. 1 illustrates a light emitting display apparatus according to an embodiment of the present disclosure.

FIG. 2 is a circuit diagram illustrating a subpixel of a light emitting display apparatus according to an embodiment of the present disclosure.

FIG. 3 illustrates a plurality of subpixel in a display panel according to an embodiment of the present disclosure.

FIG. 4 is a cross-sectional view taken along line I-I′ of FIG. 3 according to an embodiment of the present disclosure.

FIG. 5 illustrates a plurality of subpixel in a display panel according to one embodiment of the present disclosure.

FIG. 6 is a cross-sectional view taken along line II-II′ of FIG. 5 according to one embodiment of the present disclosure.

FIG. 7 illustrates a plurality of subpixel in a display panel according to another embodiment of the present disclosure.

FIG. 8 is a cross-sectional view taken along line III-III′ of FIG. 7 according to another embodiment of the present disclosure.

FIG. 9 illustrates a plurality of subpixel in a display panel according to another embodiment of the present disclosure.

FIG. 10 is a cross-sectional view taken along line IV-IV′ of FIG. 9 according to another embodiment of the present disclosure.

FIG. 11 illustrates a plurality of subpixel in a display panel according to another embodiment of the present disclosure.

FIG. 12 is a cross-sectional view taken along line V-V′ of FIG. 11 according to another embodiment of the present disclosure.

FIG. 13 illustrates a plurality of subpixel in a display panel according to another embodiment of the present disclosure.

FIG. 14 is a cross-sectional view taken along line VI-VI′ of FIG. 13 according to another embodiment of the present disclosure.

FIG. 15 illustrates a plurality of subpixel in a display panel according to another embodiment of the present disclosure.

FIG. 16 is a cross-sectional view taken along line VII-VII′ of FIG. 15 according to another embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction of thereof may be exaggerated for clarity, illustration, and/or convenience.

### DETAILED DESCRIPTION

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete, to assist those skilled in the art to understand the inventive concepts without limiting the protected scope of the present disclosure.

Shapes (e.g., sizes, lengths, widths, heights, thicknesses, locations, radii, diameters, and areas), sizes, ratios, angles, numbers, and the like disclosed herein, including those illustrated in the drawings are merely examples, and thus, the present disclosure is not limited to the illustrated details. Any implementation described herein as an “example” is not necessarily to be construed as preferred or advantageous over other implementations. It is, however, noted that the relative dimensions of the components illustrated in the drawings are part of the present disclosure.

When the term “comprise,” “have,” “include,” “contain,” “constitute,” “made of,” “formed of,” or the like is used with respect to one or more elements, one or more other elements may be added unless a term such as “only” or the like is used. The terms used in the present disclosure are merely used in order to describe example embodiments and are not intended to limit the scope of the present disclosure. The terms of a singular form may include plural forms unless the context clearly indicates otherwise.

In construing an element, the element is construed as including an error region although there is no explicit description thereof.

In describing a positional relationship, for example, when the positional order is described as “on,” “above,” “below,” “beneath”, and “next,” the case of no contact therebetween may be included, unless “just” or “direct” is used.

If it is mentioned that a first element is positioned “on” a second element, it does not mean that the first element is essentially positioned above the second element in the figure. The upper part and the lower part of an object concerned may be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

For the expression that an element is “connected,” “coupled,” “attached,” “adhered,” or the like to another element, the element may not only be directly connected, coupled, attached, adhered, or the like to another element, but also be indirectly connected, coupled, attached, adhered, or the like to another element with one or more intervening elements disposed or interposed between the elements, unless otherwise specified.

For the expression that an element is “contacts,” “overlaps,” or the like with another element, the element may not only directly contact, overlap, or the like with another element, but also indirectly contact, overlap, or the like with another element with one or more intervening elements disposed or interposed between the elements, unless otherwise specified.

The term “at least one” should be understood as including any and all combinations of one or more of the associated listed items. For example, “at least one among a first element, a second element and a third element” may include all combinations of two or more elements selected from the first, second and third elements as well as each element of the first, second and third elements.

Features of various embodiments of the present disclosure may be partially or entirety coupled to or combined with each other, may be technically associated with each other, and may be variously inter-operated, linked or driven together. The embodiments of the present disclosure may be implemented or carried out independently of each other or may be implemented or carried out together in a co-dependent or related relationship. In one or more aspects, the components of each apparatus according to various embodiments of the present disclosure are operatively coupled and configured.

In the following description, various example embodiments of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

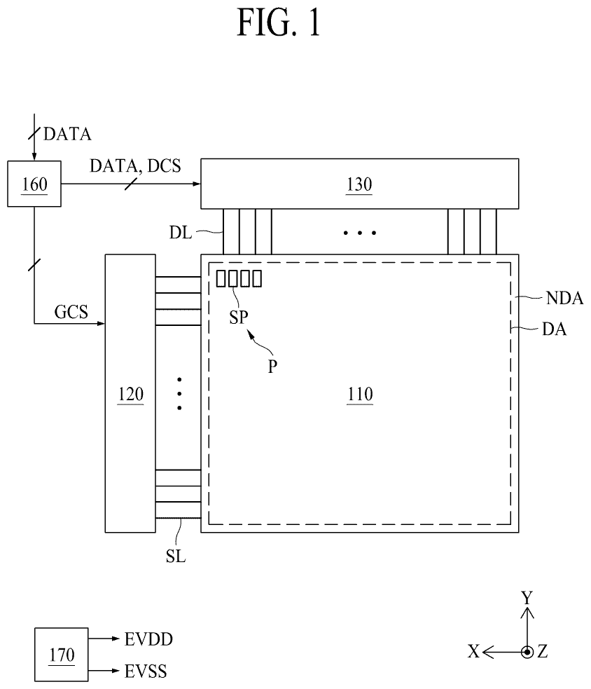

FIG. 1 illustrates a light emitting display apparatus according to an embodiment of the present disclosure.

Hereinafter, an X-axis represents a direction parallel to a scan line, a Y-axis represents a direction parallel to a data line, and a Z-axis represents a height direction of the light emitting display apparatus.

A light emitting display apparatus according to an embodiment of the present disclosure is implemented as an organic light emitting display apparatus, but may also be implemented as a liquid crystal display apparatus, a quantum dot lighting emitting diode display apparatus, or an electrophoretic display apparatus.

Referring to FIG. 1, the light emitting display apparatus according to an embodiment of the present disclosure may include a display panel 110, a scan driver 120 (or a gate driver) embedded in the display panel 110, a data driver 130 connected to the display panel 110, a timing controller 160 controlling the scan driver 120 and the data driver 130, and a power circuit 170.

The display panel 110 includes a display area DA and a non-display area NDA surrounding the display area DA. The display panel 110 includes pixels P provided in the display area DA to display an image. Each of the pixels P may include a plurality of subpixels SP. The structure of the subpixel SP may be variously changed according to the type of the light emitting display apparatus. For example, the subpixels SP may be formed in a top emission type, a bottom emission type, or a dual emission type according to the structure. The subpixels SP indicate a unit capable of forming a color filter of a specific type or capable of emitting a color of light by itself without forming a color filter. The subpixels SP may have one or more different light-emitting areas according to light-emitting characteristics. For example, the plurality of subpixels SP may be arranged in a stripe type or a quad type, but embodiments of the present disclosure are not limited thereto. The color type, arrangement type, arrangement order, and the like of the subpixels SP may be configured in various forms according to the light-emitting characteristics, lifespan of the apparatus, spec of the apparatus, and the like.

The display panel 110 may include data lines DL and scan lines SL (or gate lines) connected to the subpixels SP. The data lines DL may be arranged to cross the scan lines SL. Each of the subpixels SP of the display panel 110 may be connected to any one of the data lines DL and any one of the scan lines SL. The data lines DL may supply a data voltage supplied from the data driver 130 to each of the subpixels SP. The scan lines SL may supply a scan signal supplied from the scan driver 120 to each of the subpixels SP.

Each of the subpixels SP is turned-on by the scan signal. When the data voltage of the data line DL is supplied to a gate electrode of a driving transistor, a light emitting element may emit light according to a drain-to-source current of the driving transistor. The scan driver 120 may receive a scan control signal GCS from the timing controller 160. The scan driver 120 may supply the scan signals or emission control signal to the scan lines SL by using the scan control signal GCS.

The scan driver 120 may be configured in a gate driver in panel GIP manner in the non-display area NDA outside one side or both sides of the display area DA. Alternatively, the scan driver 120 may be manufactured as a driving chip, mounted on a flexible film, and attached to the non-display area NDA outside one side or both sides of the display area DA in a tape automated bonding TAB manner.

The data driver 130 may receive digital video data DATA and a data control signal DCS from the timing controller 160. The data driver 130 converts the digital video data DATA into analog positive/negative data voltages by using the data control signal DCS and supplies the analog positive/negative data voltages to the data lines DL.

The timing controller 160 receives digital video data DATA and timing signals from a host system. The timing signals may include a vertical synchronization signal, a horizontal synchronization signal, a data enable signal, a dot clock, and the like. The vertical synchronization signal is a signal defining one frame period. The horizontal synchronization signal is a signal defining one horizontal period required for supplying the data voltages to the pixels of one horizontal line of the display panel 110. The data enable signal defines a period in which valid data is input. The dot clock is a signal repeated at a predetermined short period.

The timing controller 160 may generate the data control signal DCS for controlling an operation timing of the data driver 130 and the scan control signal GCS for controlling an operation timing of the scan driver 120 based on the timing signals. The timing controller 160 may output the scan control signal GCS to the scan driver 120 to control the scan driver 120 and output the digital video data DATA and data control signal DCS to the data driver 130 to control the data driver 130.

The power circuit 170 may generate and supply a plurality of driving voltages required for an operation of all circuit configurations of the light emitting display apparatus by using an input voltage. The power circuit 170 may generate a first power source voltage EVDD (or pixel power voltage), a second power supply voltage EVSS (or common power voltage) and an initialization voltage Vref (or reference voltage) and supply the generated voltages to the display panel 110. The power circuit 170 may generate and supply various driving voltages required for operations of the scan driver 120, the data driver 130, and the timing controller 160.

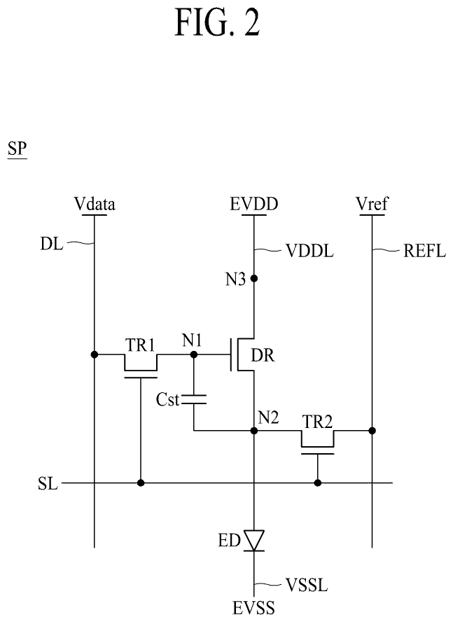

FIG. 2 is a circuit diagram illustrating a subpixel of a light emitting display apparatus according to an embodiment of the present disclosure.

Referring to FIG. 2, each of plurality of pixels P includes the plurality of subpixels SP constituting a unit pixel. In each of the plurality of subpixels SP, there are a pixel circuit having 3T (Transistor) 1C (Capacitor) including the driving transistor DR, the first switching transistor TR1, the second switching transistor TR2 and the storage capacitor Cst, and the light emitting device ED, but not limited thereto. Each subpixel SP may further include a compensation circuit. In this case, the subpixel SP may have various structures such as 3T2C, 4T1C, 4T2C, 5T1C, 5T2C, 6T1C, 6T2C, 7T1C, and 7T2C.

At least one thin film transistor DR, TR1, and TR2 of each subpixel SP may include a gate electrode, a source electrode, and a drain electrode. Since the source electrode and the drain electrode may be changed according to a voltage and a current direction applied to the gate electrode without being fixed, any one of the source electrode and the drain electrode may be represented as a first electrode, and the other may be represented as a second electrode. The at least one transistor DR, TR1, and TR2 may use at least one of polysilicon semiconductor, amorphous silicon semiconductor, and oxide semiconductor. The transistors DR, TR1, and TR2 may be P-type or N-type, or P-type and N-type may be interchangeably used.

The driving transistor DR corresponds to a transistor for driving the light emitting device ED, and the driving transistor DR includes the first node N1 to which the data voltage Vdata is applied, the second node N2 connected to a pixel electrode (first electrode or anode electrode) of the light emitting device ED, and the third node N3 connected to the first power voltage line VDDL (or pixel power voltage line) and supplied with the first power voltage EVDD (or pixel power voltage). For example, the driving transistor DR may generate a data current from the first power voltage EVDD supplied from the first power voltage line VDDL and may supply the data current to the first electrode of the light emitting device ED.

The first switching transistor TR1 may serve to supply the data voltage Vdata supplied from the data line DL to the first node N1 of the driving transistor DR. The second switching transistor TR2 may serve to supply the reference voltage Vref supplied from the reference line REFL to the second node N2 of the driving transistor DR or may output a voltage of the second node N2 of the driving transistor DR. The storage capacitor Cst may be connected between the first node N1 and the second node N2 of the driving transistor DR. The storage capacitor Cst may serve to maintain the data voltage Vdata supplied to the driving transistor DR for one frame, but embodiments of the present disclosure are not limited thereto.

The light emitting device ED may include the pixel electrode (first electrode or anode electrode) connected to the second node N2 of the driving transistor DR, and the common electrode (second electrode or cathode electrode) connected to the second power voltage line VSSL. The light emitting device ED may emit light in response to a driving current generated by the driving transistor DR through an emission layer (or organic emission layer) between the first electrode and the second electrode. The pixel electrode of the light emitting device ED may be an independent electrode for each light emitting device, and the common electrode and the emission layer of the light-emitting device ED may be a common layer shared by the entire light emitting devices, but embodiments of the present disclosure are not limited thereto.

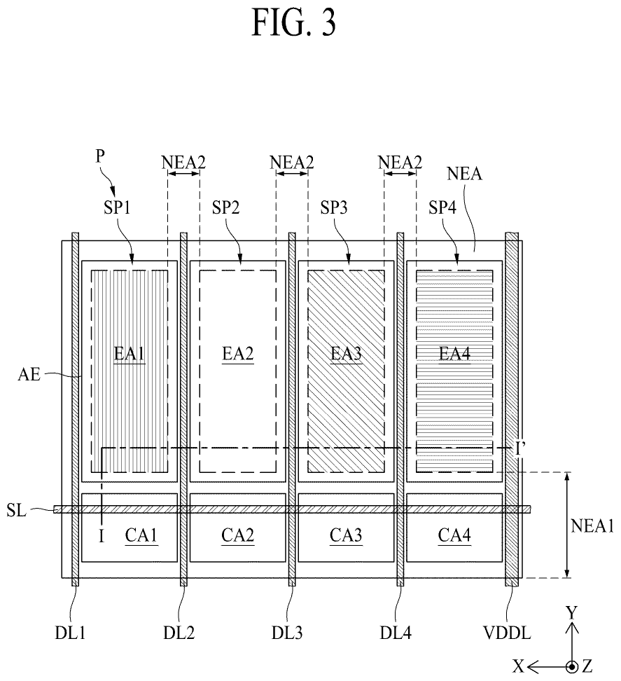

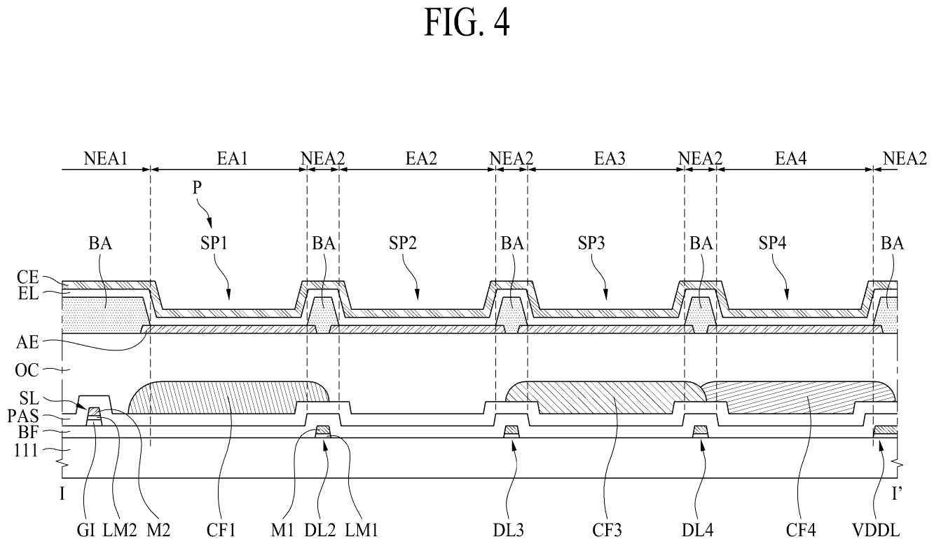

FIG. 3 illustrates a plurality of subpixel in a display panel according to an embodiment of the present disclosure. FIG. 4 is a cross-sectional view taken along line I-I′ of FIG. 3 according to an embodiment of the present disclosure.

Referring to FIGS. 3 and 4, the display panel 110 according to an embodiment of the present disclosure may be configured to a top emission type, a bottom emission type, or a dual emission type. For example, the display panel 110 may be implemented in the bottom emission type.

The display panel 110 according to an embodiment of the present disclosure may include the plurality of subpixels SP1, SP2, SP3, and SP4, the plurality of data lines DL1, DL2, DL3, and DL4, at least one scan line SL (or gate line), the first power voltage line VDDL, pixel circuits CA1, CA2, CA3, and CA4, and at least one color filter CF1, CF3 and CF4.

The plurality of subpixels SP1, SP2, SP3, and SP4 may be unit pixels that emit different colors. The plurality of subpixels SP1, SP2, SP3, and SP4 may be arranged in a stripe type in a first direction (or X-axis direction) or a second direction (or Y-axis direction). For example, the plurality of subpixels SP1, SP2, SP3, and SP4 may be arranged in the first direction (or X-axis direction), but not limited thereto. The arrangement order or type of the plurality of subpixels may be variously changed.

The plurality of subpixels SP1, SP2, SP3, and SP4 may include emission areas EA1, EA2, EA3, and EA4 in which the light emitting device ED is disposed to emit light, and the non-emission area NEA. For example, the non-emission area NEA may include the first non-emission area NEA1 in which the pixel circuits CA1, CA2, CA3, and CA4 are disposed, and the second non-emission area NEA2 between adjacent subpixels SP1, SP2, SP3, and SP4. For example, at least one scan line SL extending in the first direction (or X-axis direction) may be disposed in the first non-emission area NEA1, and the plurality of data lines DL1, DL2, DL3, and DL4 and the first power voltage line VDDL extending in the second direction (or Y-axis direction) may be disposed in the second non-emission area NEA2.

The emission areas EA1, EA2, EA3, and EA4 may correspond to regions that emit light in each subpixel SP1, SP2, SP3, and SP4. For example, each subpixel SP1, SP2, SP3, and SP4 may include the light emitting device ED including the pixel electrode AE, an emission layer EL, and the common electrode CE, and the emission areas EA1, EA2, EA3, and EA4 may overlap the light emitting device ED of each subpixel SP1, SP2, SP3, and SP4. The emission areas EA1, EA2, EA3, and EA4 may include first to fourth emission areas EA1, EA2, EA3, and EA4 that emit light of different colors. For example, the first to fourth emission areas EA1, EA2, EA3, and EA4 may be opening areas of the pixel electrode AE defined by the bank portion BA.

The first to fourth emission areas EA1, EA2, EA3, and EA4 may emit light of different colors through at least one color filter CF1, CF3, and CF4. For example, the at least one color filter CF1, CF3, and CF4 may emit light of different colors. For example, the at least one color filter CF1, CF3, and CF4 may be formed of an organic material that transmits light of different colors. The at least one color filter CF1, CF3, and CF4 may include the first color filter CF1 that transmits red light, the third color filter CF3 that transmits blue light, and the fourth color filter CF4 that transmits green light. For example, the first emission area EA1 of the first subpixel SP1 may emit red light through the first color filter CF1, the second emission area EA2 of the second subpixel SP2 may emit white light either without a color filter or through a color filter that transmits white light, the third emission area EA3 of the third subpixel SP3 may emit blue light through the third color filter CF3, and the fourth emission area EA4 of the fourth subpixel SP4 may emit green light through the fourth color filter CF4, but embodiments of the present disclosure are not limited thereto.

The at least one scan line SL (or gate line) may be disposed to overlap the first non-emission area NEA1 in which the pixel circuits CA1, CA2, CA3, and CA4 are disposed. The at least one scan line SL may extend in the first direction (or X-axis direction) to cross the first non-emission area NEA1. The at least one scan line SL may supply a scan signal to at least one thin film transistor TR1 and TR2 included in the pixel circuits CA1, CA2, CA3, and CA4. For example, the at least one scan line SL may be formed of the same material in the same layer as a gate electrode of the at least one thin film transistor DR, TR1 and TR2 disposed in the pixel circuits CA1, CA2, CA3, and CA4. For example, the at least one scan line SL may include a low-reflectance material layer to reduce external light reflection.

The plurality of data lines DL1, DL2, DL3, and DL4 may be disposed to correspond to each subpixel SP1, SP2, SP3, and SP4. The plurality of data lines DL1, DL2, DL3, and DL4 may be disposed to overlap the second non-emission area NEA2 between adjacent subpixels SP1, SP2, SP3, and SP4. The plurality of data lines DL1, DL2, DL3, and DL4 may extend in a second direction (or Y-axis direction) in the second non-emission area NEA2. The plurality of data lines DL1, DL2, DL3, and DL4 may be disposed on the left or right side of each subpixel SP1, SP2, SP3, and SP4, but embodiments of the present disclosure are not limited thereto. For example, the first data line DL1 may be disposed on the left side of the first subpixel SP1 to supply a data voltage to the first subpixel SP1, the second data line DL2 may be disposed on the left side of the second subpixel SP2 to supply a data voltage to the second subpixel SP2, the third data line DL3 may be disposed on the left side of the third subpixel SP3 to supply a data voltage to the third subpixel SP3, and the fourth data line DL4 may be disposed on the left side of the fourth subpixel SP4 to supply a data voltage to the fourth subpixel SP4. For example, each data line DL1, DL2, DL3, and DL4 may be formed of the same material in the same layer as the light blocking layer disposed in the pixel circuit. Each data line DL1, DL2, DL3, and DL4 may include a low-reflectance material layer to reduce external light reflection.

The first power voltage line VDDL may be disposed to correspond to the plurality of subpixels SP1, SP2, SP3, and SP4. The first power voltage line VDDL may be disposed to overlap the second non-emission area NEA2 on the left or right side of the plurality of subpixels SP1, SP2, SP3 and SP4. Alternatively, the first power voltage line VDDL may be disposed within the plurality of subpixels SP1, SP2, SP3 and SP4. For example, the first power voltage line VDDL may be disposed to overlap the second non-emission area NEA2 between the second and third subpixels SP2 and SP3, but embodiments of the present disclosure are not limited thereto. The first power voltage line VDDL may be formed of the same material in the same layer as the plurality of data lines DL1, DL2, DL3 and DL4, but embodiments of the present disclosure are not limited thereto.

Referring to FIG. 4, the display panel 110 according to an embodiment of the present disclosure may include the substrate 111, the plurality of data lines DL1, DL2, DL3, and DL4, the first power voltage line VDDL, at least one scan line SL, at least one insulating layer BF, GI and PAS, at least one color filter CF1, CF3 and CF4, the planarization layer OC, the pixel electrode AE, the emission layer EL, and the common electrode CE. For example, the display panel 110 may further include the bank portion BA disposed on the planarization layer OC and the pixel electrode AE.

At least one signal line and power voltage line may be disposed on the substrate 111. For example, the plurality of data lines DL1, DL2, DL3, and DL4 and the first power voltage line VDDL may be disposed on the substrate 111. For example, the plurality of data lines DL1, DL2, DL3, and DL4 and the first power voltage line VDDL may be formed of the same material in the same layer as a light blocking layer disposed in the pixel circuits CA1, CA2, CA3, and CA4.

The plurality of data lines DL1, DL2, DL3, and DL4 and the first power voltage line VDDL disposed at the lowermost portion of the substrate 111 may include a low-reflectance material layer for reducing external light reflection and may include the conductive metal layer M1 and the low-reflectance material layer LM1 below the metal layer M1. For example, the metal layer M1 may be configured as a single layer or a multilayer of any one or more of molybdenum Mo, aluminum Al, chromium Cr, tungsten W, gold Au, titanium Ti, nickel Ni, neodymium Nd, and copper Cu, or an alloy thereof, but embodiments of the present disclosure are not limited thereto. The low-reflectance material layer LM1 may be a metal layer having excellent low-reflectance characteristics and may be configured of molybdenum-titanium MoTi or molybdenum Mo or may include a metal oxide or an alloy oxide. For example, the low-reflectance material layer LM1 may include copper oxide CuOx, nickel oxide NiOx, molybdenum oxide MoOx, or tungsten oxide WOx, but embodiments of the present disclosure are not limited thereto. For example, the plurality of data lines DL1, DL2, DL3 and DL4 and the first power voltage line VDDL may be a dual-layer structure that includes copper Cu and molybdenum-titanium MoTi, or copper Cu and a metal oxide.

The at least one insulating layer BF, GI, and PAS may be disposed on the substrate 111. The at least one insulating layer BF, GI and PAS may include the buffer layer BF, the gate insulating layer GI, and the passivation layer PAS. For example, the buffer layer BF may be disposed on the substrate 111. The buffer layer BF may be configured to cover at least one signal line and power voltage line, and the light blocking layer on the substrate 111. The gate insulating layer GI, the passivation layer PAS, and at least one thin film transistor may be disposed on the buffer layer BF. For example, the at least one insulating layer BF, GI and PAS may be configured as a single layer or a multilayer that includes an inorganic insulating material such as silicon oxide SiOₓ, silicon nitride SiNₓ, or aluminum oxide Al₂O₃, but embodiments of the present disclosure are not limited thereto.

The at least one scan line SL (or gate line) may be disposed on the gate insulating layer GI. The at least one scan line SL may be disposed on the gate insulating layer GI and may be patterned together with the gate insulating layer GI. The at least one scan line SL may be configured in the same layer and with the same material as a gate electrode of at least one thin film transistor disposed in the pixel circuit CA1, CA2, CA3 and CA4.

The at least one scan line SL may include a low-reflectance material layer for reducing external light reflection. For example, the at least one scan line SL may include the conductive metal layer M2 and the low-reflectance material layer LM2 below the metal layer M2. For example, the metal layer M2 may be configured as a single layer or a multilayer of any one or more of molybdenum Mo, aluminum Al, chromium Cr, tungsten W, gold Au, titanium Ti, nickel Ni, neodymium Nd, and copper Cu, or an alloy thereof, but embodiments of the present disclosure are not limited thereto. The low-reflectance material layer LM2 may be a metal layer with excellent low-reflectance characteristics and may be configured with molybdenum-titanium MoTi or molybdenum Mo or may include a metal oxide or an alloy oxide. For example, the low-reflectance material layer LM2 may include copper oxide CuOx, nickel oxide NiOx, molybdenum oxide MoOx, or tungsten oxide WOx, but embodiments of the present disclosure are not limited thereto. For example, the at least one scan line SL may be configured as a double-layer structure including copper Cu and molybdenum-titanium MoTi, or copper Cu and a metal oxide.

The passivation layer PAS may be disposed on the at least one scan line SL, and at least one color filter CF1, CF3 and CF4 may be disposed on the passivation layer PAS. The at least one color filter CF1, CF3 and CF4 may be disposed to correspond to the first subpixel SP1, the third subpixel SP3, and the fourth subpixel SP4 among the first to fourth subpixels SP1, SP2, SP3 and SP4. A color filter may not be disposed in the second subpixel SP2 among the first to fourth subpixels SP1, SP2, SP3, and SP4. For example, the first color filter CF1 that converts white light emitted from the light emitting device ED into red light may be disposed in the first emission area EA1 of the first subpixel SP1. The second emission area EA2 of the second subpixel SP2 may emit white light as it is without a color filter. The third color filter CF3 that converts white light emitted from the light emitting device ED into blue light may be disposed in the third emission area EA3 of the third subpixel SP3. The fourth color filter CF4 that converts white light emitted from the light emitting device ED into green light may be disposed in the fourth emission area EA4 of the fourth subpixel SP4.

The planarization layer OC (or an overcoat layer) may be disposed on the passivation layer PAS and at least one color filter CF1, CF3, and CF4. The planarization layer OC may planarize step differences caused by at least one signal line and power voltage line, at least one thin-film transistor, and at least one color filter CF1, CF3, and CF4 disposed on the substrate 111, and may be formed of an organic insulating material. For example, the planarization layer OC may be formed of an organic material such as acryl resin, epoxy resin, phenolic resin, polyamide resin, or polyimide resin, but embodiments of the present disclosure are not limited thereto.

The pixel electrode AE (first electrode or anode electrode), the emission layer EL (or organic emission layer), and the common electrode CE (second electrode or cathode electrode) that constitute the light emitting device ED may be disposed on the planarization layer OC. Also, the bank portion BA configured to define an opening area (or emission area) of the pixel electrode AE may be further disposed on the planarization layer OC.

The pixel electrode AE may be disposed on the planarization layer OC. The pixel electrode AE may be patterned and disposed for each subpixel SP1, SP2, SP3 and SP4 on the planarization layer OC. The pixel electrode AE may be formed of a transparent metal material or a semi-transmissive metal material. For example, the pixel electrode AE may be formed of a transparent conductive material TCO such as indium tin oxide ITO or indium zinc oxide IZO that may transmit light. The pixel electrode AE may be formed of a semi-transmissive conductive material such as magnesium Mg, silver Ag, or an alloy of magnesium Mg and silver Ag. For example, the pixel electrode AE formed of the semi-transmissive metal material may improve light extraction efficiency by a micro cavity. The pixel electrode AE may be an anode electrode of the light emitting device ED. According to an embodiment of the present disclosure, the pixel electrode AE may further include a low-reflectance metal layer. For example, the low-reflectance metal layer may include a metal oxide or an alloy oxide. For example, the low-reflectance metal layer may include copper oxide CuOx, nickel oxide NiOx, molybdenum oxide MoOx, or tungsten oxide WOx, but embodiments of the present disclosure are not limited thereto.

The bank portion BA may be disposed on the pixel electrode AE and the planarization layer OC. The bank portion BA may be disposed on the planarization layer OC to cover a portion of the edge of the pixel electrode AE. The bank portion BA may be configured to define an opening area (or emission area) of the pixel electrode AE. For example, the bank portion BA may be disposed between the pixel electrode AE and the emission layer EL. The opening area of the pixel electrode AE may correspond to the emission areas EA1, EA2, EA3, and EA4 of each subpixel SP1, SP2, SP3, and SP4. For example, the pixel electrode AE exposed by the bank portion BA may be electrically connected by being in direct contact with the emission layer EL and the common electrode CE, thereby forming the light emitting device ED. For example, the bank portion BA may be omitted.

The bank portion BA may be disposed in the non-emission area NEA of each subpixel SP1, SP2, SP3, and SP4. The bank portion BA may overlap the pixel circuits CA1, CA2, CA3, and CA4, at least one signal line, and power voltage line. For example, the bank portion BA may be formed of an organic layer such as acryl resin, epoxy resin, phenolic resin, polyamide resin, or polyimide resin. For example, the bank portion BA may be a black bank that includes at least one of a light-absorbing material or a black material. For example, the bank portion BA may include an insulating light-absorbing material such as black resin or graphite, but embodiments of the present disclosure are not limited thereto.

The emission layer EL (or organic emission layer) may be disposed on the pixel electrode AE and the bank portion BA. The emission layer EL may include a hole transporting layer, an emission material layer, and an electron transporting layer. For example, when a voltage is applied to the pixel electrode AE and the common electrode CE, holes and electrons may move to the emission layer EL through the hole transporting layer and the electron transporting layer, respectively, and may be combined with each other in the emission layer EL to emit light. The emission layer EL may be a common layer commonly formed over the plurality of subpixels SP1, SP2, SP3 and SP4. For example, the emission layer EL may be a white emission layer that emits white light.

The common electrode CE may be disposed on the emission layer EL. The common electrode CE may be a common layer commonly formed over the plurality of subpixels SP1, SP2, SP3, and SP4. The common electrode CE may be disposed on the pixel electrode AE and the emission layer EL, which are in contact with each other, to constitute the light emitting device ED. For example, the common electrode CE may be formed of a metal material having high reflectance, such as a stacked structure (Ti/Al/Ti) of aluminum and titanium, a stacked structure (ITO/Al/ITO) of aluminum and ITO, Ag alloy, a stacked structure (ITO/Ag alloy/ITO) of Ag alloy and ITO, MoTi alloy, and a stacked structure (ITO/MoTi alloy/ITO) of MoTi alloy and ITO. The Ag alloy may be an alloy of silver (Ag), palladium (Pd), copper (Cu) and the like. The MoTi alloy may be an alloy of molybdenum (Mo) and titanium (Ti). The common electrode CE may be a cathode electrode of the light emitting device ED. According to an embodiment of the present disclosure, the common electrode CE may further include a low-reflectance metal layer. For example, the low-reflectance metal layer may include a metal oxide or an alloy oxide. For instance, the low-reflectance metal layer may include copper oxide (CuOx), nickel oxide (NiOx), molybdenum oxide (MoOx), or tungsten oxide (WOx), but embodiments of the present disclosure are not limited thereto.

According to embodiments of the present disclosure, a transmittance control film may be further included on a rear surface of the substrate 111. For example, the transmittance control film may include at least one of a transparent film or an absorptive film, but embodiments of the present disclosure are not limited thereto.

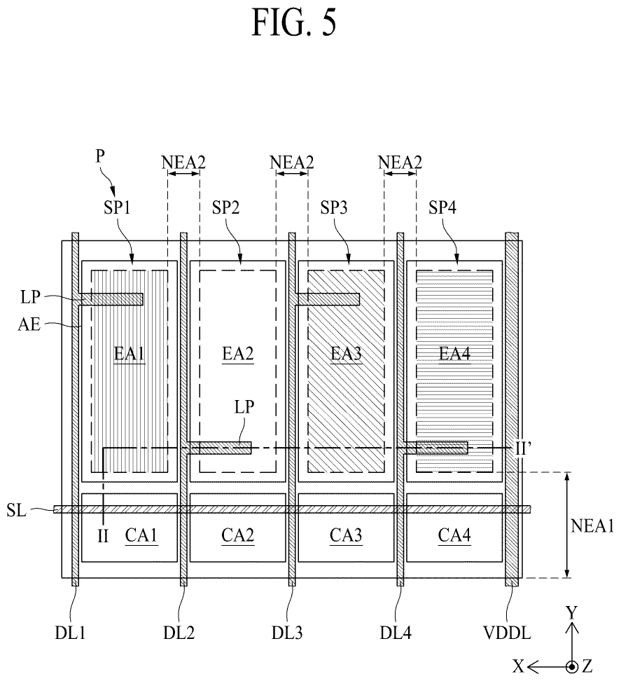

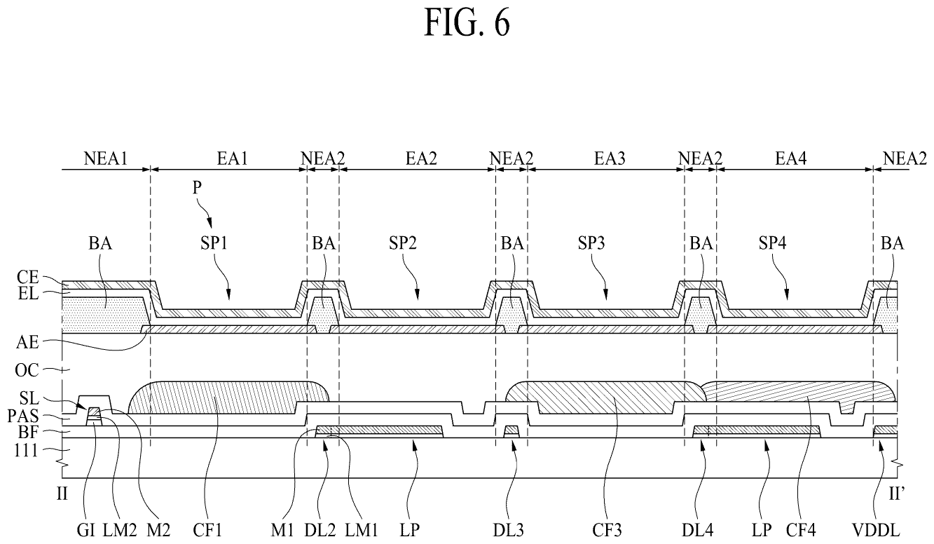

FIG. 5 illustrates a plurality of subpixel in a display panel according to one embodiment of the present disclosure. FIG. 6 is a cross-sectional view taken along line II-II′ of FIG. 5 according to one embodiment of the present disclosure. FIGS. 5 and 6 illustrate one embodiment of the present disclosure in which a low-reflectance pattern configuration is additionally provided in the light emitting display apparatus described with reference to FIGS. 1 to 4. In the following description referring to FIGS. 5 and 6, the same reference numerals will be used for the same components, except for the added low-reflectance pattern, and their redundant description will be omitted or briefly described.

Referring to FIGS. 5 and 6, the display panel 110 according to one embodiment of the present disclosure may include the low-reflectance pattern LP overlapping at least one of emission areas EA1, EA2, EA3 and EA4 among the plurality of subpixels SP1, SP2, SP3 and SP4. The low-reflectance pattern LP may be disposed in some or all of the plurality of subpixels SP1, SP2, SP3 and SP4.

The low-reflectance pattern LP according to one embodiment of the present disclosure may be configured to optimize the cell reflectance of the emission areas EA1, EA2, EA3 and EA4 while maintaining the area of the emission areas EA1, EA2, EA3 and EA4 to be suitable for a pol-less structure that does not use a polarizing plate. The low-reflectance pattern LP may include a low-reflectance material layer for reducing external light reflection.

The low-reflectance pattern LP according to one embodiment of the present disclosure may be disposed to overlap at least one color filter CF1, CF3 and CF4 in the emission areas EA1, EA2, EA3 and EA4. Also, the low-reflectance pattern LP may be disposed to overlap the pixel electrode AE in the emission areas EA1, EA2, EA3 and EA4. The at least one color filter CF1, CF3 and CF4 may be between the pixel electrode AE and the low-reflectance pattern LP.

The low-reflectance pattern LP according to one embodiment of the present disclosure may be formed of the same material in the same layer as at least one of the data lines DL1, DL2, DL3, and DL4 or the scan line SL. The low-reflectance pattern LP may be connected to or separated from the data lines DL1, DL2, DL3 and DL4. For example, the low-reflectance pattern LP may be integrally formed with the data lines DL1, DL2, DL3 and DL4 or may be formed as a separate pattern separated from the data lines DL1, DL2, DL3 and DL4. Also, the low-reflectance pattern LP may be connected to or separated from the scan line SL. For example, the low-reflectance pattern LP may be integrally formed with the scan line SL or may be formed as a separate pattern separated from the scan line SL.

Referring to FIG. 5, the low-reflectance pattern LP according to one embodiment of the present disclosure may extend in a first direction (or X-axis direction) from each data line DL1, DL2, DL3 and DL4 and be disposed to overlap the emission areas EA1, EA2, EA3 and EA4.

The low-reflectance pattern LP extending in the first direction from the first data line DL1 may be disposed in the first emission area EA1 of the first subpixel SP1, the low-reflectance pattern LP extending in the first direction from the second data line DL2 may be disposed in the second emission area EA2 of the second subpixel SP2, the low-reflectance pattern LP extending in the first direction from the third data line DL3 may be disposed in the third emission area EA3 of the third subpixel SP3, and the low-reflectance pattern LP extending in the first direction from the fourth data line DL4 may be disposed in the fourth emission area EA4 of the fourth subpixel SP4.

The low-reflectance pattern LP extending from the first and third data lines DL1 and DL3 may be disposed above the first and third emission areas EA1 and EA3 with respect to a second direction (or Y-axis direction), and the low-reflectance pattern LP extending from the second and fourth data lines DL2 and DL4 may be disposed below the second and fourth emission areas EA2 and EA4 with respect to the second direction (or Y-axis direction).

According to one embodiment of the present disclosure, the low-reflectance pattern LP may extend in one or more portions from each of the data lines DL1, DL2, DL3, and DL4, the low-reflectance pattern LP may be disposed in one or more portions in each of the emission areas EA1, EA2, EA3 and EA4, and the low-reflectance pattern LP may be disposed only in some of the emission areas EA1, EA2, EA3, and EA4, but embodiments of the present disclosure are not limited thereto.

Referring to FIG. 6, the low-reflectance pattern LP according to one embodiment of the present disclosure may be disposed on the substrate 111. The low-reflectance pattern LP according to one embodiment of the present disclosure may be configured with the same material in the same layer as the data lines DL1, DL2, DL3, and DL4 and the first power voltage line VDDL on the substrate 111. The low-reflectance pattern LP may include a low-reflectance material layer for reducing the reflection of external light. The low-reflectance pattern LP may include the conductive metal layer M1 and the low-reflectance material layer LM1 below the metal layer M1. For example, the metal layer M1 may be configured as a single layer or a multilayer formed of any one of molybdenum Mo, aluminum Al, chromium Cr, tungsten W, gold Au, titanium Ti, nickel Ni, neodymium Nd, and copper Cu, or an alloy thereof, but embodiments of the present disclosure are not limited thereto. The low-reflectance material layer LM1 may be a metal layer having excellent low-reflectance characteristics and may be configured of molybdenum-titanium MoTi or molybdenum Mo or may include a metal oxide or an alloy oxide. For example, the low-reflectance material layer LM1 may include copper oxide CuOx, nickel oxide NiOx, molybdenum oxide MoOx, or tungsten oxide WOx, but embodiments of the present disclosure are not limited thereto. For example, the low-reflectance pattern LP may be a dual-layer structure that includes copper Cu and molybdenum-titanium MoTi, or copper Cu and a metal oxide.

One end of the low-reflectance pattern LP may be connected to each data line DL1, DL2, DL3 and DL4, and another end of the low-reflectance pattern LP may be electrically floated. The low-reflectance pattern LP may overlap the at least one color filter CF1, CF3 and CF4 and may overlap the pixel electrode AE of each subpixel SP1, SP2, SP3 and SP4. The at least one color filter CF1, CF3 and CF4 may be disposed between the pixel electrode AE and the low-reflectance pattern LP.

A lower portion of the low-reflectance pattern LP includes the low-reflectance material layer LM1 having a lower reflectance than the pixel electrode AE and the common electrode CE. By reflecting or absorbing a portion of externally incident light through the lower portion of the low-reflectance pattern LP before reaching the pixel electrode AE, the cell reflectance of the emission areas EA1, EA2, EA3 and EA4 may be reduced. Also, the metal layer M1 may be disposed in the upper portion of the low-reflectance pattern LP, and the light emitted from the light emitting device ED may be internally reflected through the upper portion of the low-reflectance pattern LP, thereby improving light extraction efficiency.

According to one embodiment of the present disclosure, it is possible to reduce the reflectance of externally incident light through the low-reflectance pattern LP that overlap the emission areas EA1, EA2, EA3 and EA4, while maintaining an optimized area of the emission areas EA1, EA2, EA3 and EA4 so that current density is not increased and display quality such as image retention is not degraded. In addition, internal reflection of light emitted from the light emitting device ED may be induced through the low-reflectance pattern LP, thereby increasing light extraction efficiency. Accordingly, it is possible to provide the light emitting display apparatus capable of optimizing the cell reflectance of the emission areas EA1, EA2, EA3 and EA4 suitable for a pol-less structure and improving light efficiency.

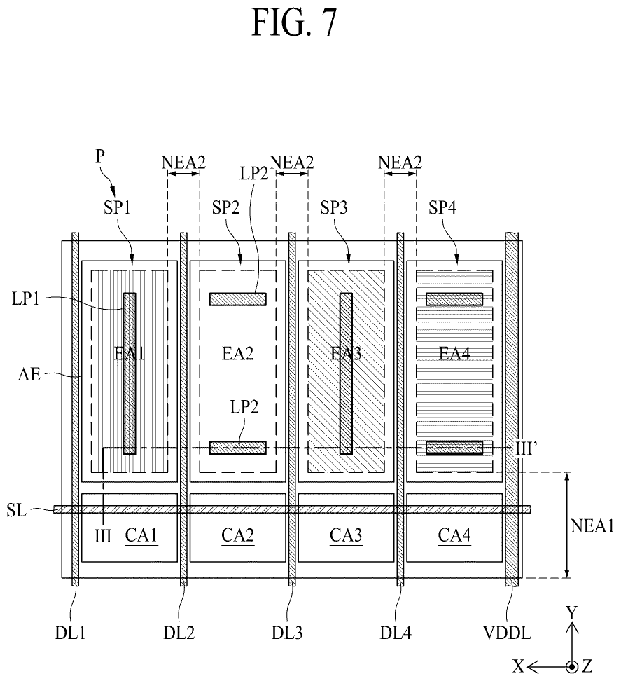

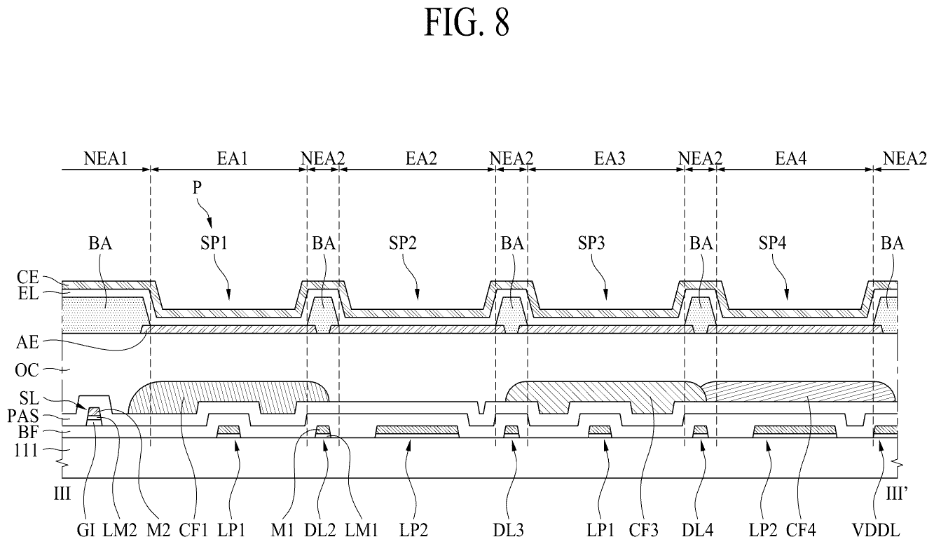

FIG. 7 illustrates a plurality of subpixel in a display panel according to another embodiment of the present disclosure. FIG. 8 is a cross-sectional view taken along line III-III′ of FIG. 7 according to another embodiment of the present disclosure. FIGS. 7 and 8 illustrate another embodiment of the present disclosure in which a low-reflectance pattern configuration is modified in the light emitting display apparatus described with reference to FIGS. 1 to 6. In the following description referring to FIGS. 7 and 8, the same reference numerals will be used for the same components, except for the modified low-reflectance pattern, and their redundant description will be omitted or briefly described.

Referring to FIGS. 7 and 8, the display panel 110 according to another embodiment of the present disclosure may include first and second low-reflectance patterns LP1 and LP2 that are configured as island patterns extending in different directions in at least one of emission areas EA1, EA2, EA3, and EA4 among the plurality of subpixels SP1, SP2, SP3, and SP4. The first and second low-reflectance patterns LP1 and LP2 may be disposed in some or all of the plurality of subpixels SP1, SP2, SP3 and SP4.

Referring to FIG. 7, the first and second low-reflectance patterns LP1 and LP2 according to another embodiment of the present disclosure may be island patterns that are spaced apart from each of data lines DL1, DL2, DL3, and DL4 and extend in a first direction (or X-axis direction) or a second direction (or Y-axis direction) in the emission areas EA1, EA2, EA3 and EA4.

At least one first low-reflectance pattern LP1 configured as an island pattern extending in the second direction may be disposed in the first emission area EA1 of the first subpixel SP1, one or more second low-reflectance patterns LP2 configured as island patterns extending in the first direction may be disposed in the second emission area EA2 of the second subpixel SP2, at least one first low-reflectance pattern LP1 configured as an island pattern extending in the second direction may be disposed in the third emission area EA3 of the third subpixel SP3, and one or more second low-reflectance patterns LP2 configured as island patterns extending in the first direction may be disposed in the fourth emission area EA4 of the fourth subpixel SP4. For example, one end and another end of the first and second low-reflectance patterns LP1 and LP2 may be electrically floated.

The first low-reflectance patterns LP1 disposed in the first and third emission areas EA1 and EA3 may be disposed at central portions of the respective emission areas EA1 and EA3 with respect to the first direction (or X-axis direction), and the second low-reflectance patterns LP2 disposed in the second and fourth emission areas EA2 and EA4 may be disposed in plural numbers at upper and lower portions of the respective emission areas EA2 and EA4 with respect to the second direction (or Y-axis direction).

According to another embodiment of the present disclosure, one or more of the first low-reflectance patterns LP1 may be disposed in each of the emission areas EA1, EA2, EA3, and EA4, and one or more of the second low-reflectance patterns LP2 may be disposed in each of the emission areas EA1, EA2, EA3, and EA4. The first and second low-reflectance patterns LP1 and LP2 may be disposed in some or all of the emission areas EA1, EA2, EA3, and EA4, but embodiments of the present disclosure are not limited thereto.

Referring to FIG. 8, the first and second low-reflectance patterns LP1 and LP2 according to another embodiment of the present disclosure may be disposed on the substrate 111. The first and second low-reflectance patterns LP1 and LP2 may be formed of the same material and in the same layer as the data lines DL1, DL2, DL3, and DL4 and the first power voltage line VDDL on the substrate 111. The first and second low-reflectance patterns LP1 and LP2 may be configured as electrically floated island patterns within each of the emission areas EA1, EA2, EA3, and EA4. The first and second low-reflectance patterns LP1 and LP2 may overlap at least one of color filters CF1, CF3, and CF4, and may overlap the pixel electrode AE of each of the subpixels SP1, SP2, SP3, and SP4. The at least one the color filters CF1, CF3 and CF4 may be disposed between the pixel electrode AE and the first and second low-reflectance patterns LP1 and LP2.

A lower portion of the first and second low-reflectance patterns LP1 and LP2 may include the low-reflectance material layer LM1 having a lower reflectance than the pixel electrode AE and the common electrode CE, and may reduce the cell reflectance of the emission areas EA1, EA2, EA3, and EA4 by reflecting or absorbing a portion of external light incident from outside through the lower portion of the first and second low-reflectance patterns LP1 and LP2 before reaching the pixel electrode AE. Also, the metal layer M1 may be disposed in an upper portion of the first and second low-reflectance patterns LP1 and LP2 to induce internal reflection of light emitted from the light emitting device ED through the upper portion of the first and second low-reflectance patterns LP1 and LP2, thereby increasing light extraction efficiency.

According to another embodiment of the present disclosure, it is possible to reduce the reflectance of externally incident light through the first and second low-reflectance patterns LP1 and LP2 that overlap the emission areas EA1, EA2, EA3, and EA4, while maintaining an optimized area of the emission areas EA1, EA2, EA3, and EA4 so that current density is not increased and display quality such as image retention is not degraded. In addition, internal reflection of light emitted from the light emitting device ED may be induced through the first and second low-reflectance patterns LP1 and LP2, thereby increasing light extraction efficiency. Accordingly, it is possible to provide the light emitting display apparatus capable of optimizing the cell reflectance of the emission areas EA1, EA2, EA3, and EA4 suitable for a pol-less structure and improving light efficiency.

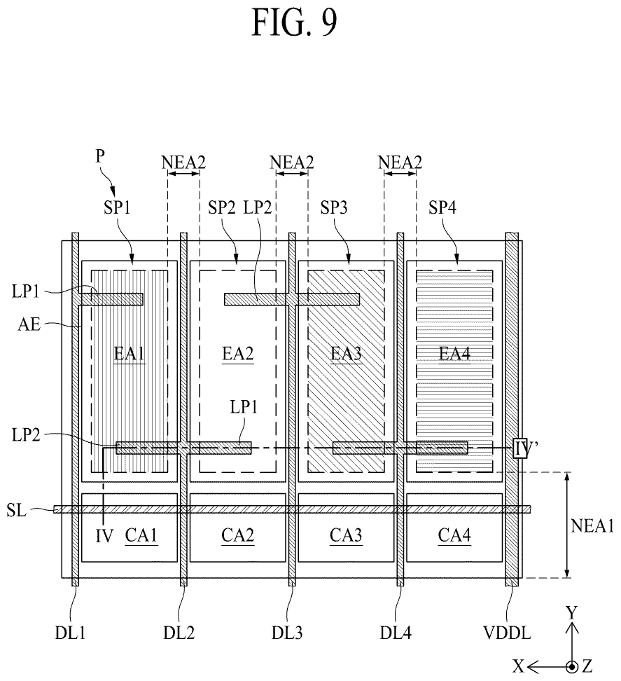

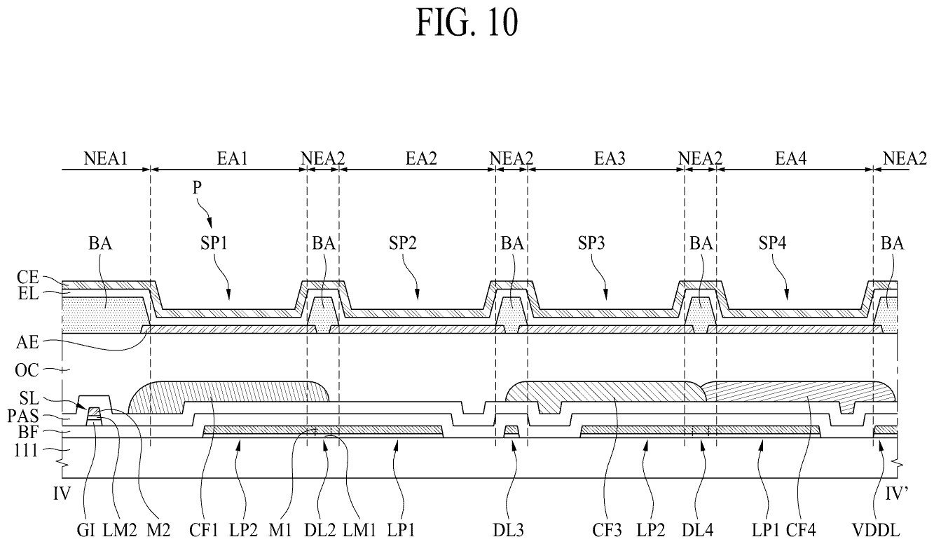

FIG. 9 illustrates a plurality of subpixels in a display panel according to another embodiment of the present disclosure. FIG. 10 is a cross-sectional view taken along line IV-IV′ of FIG. 9 according to another embodiment of the present disclosure. FIGS. 9 and 10 illustrate another embodiment of the present disclosure in which a low-reflectance pattern configuration is modified in the light emitting display apparatus described with reference to FIGS. 1 to 8. In the following description referring to FIGS. 9 and 10, the same reference numerals will be used for the same components, except for the modified low-reflectance pattern, and their redundant description will be omitted or briefly described.

Referring to FIGS. 9 and 10, the display panel 110 according to another embodiment of the present disclosure may include first and second low-reflectance patterns LP1 and LP2 that overlap at least one of the emission areas EA1, EA2, EA3, and EA4 among the plurality of subpixels SP1, SP2, SP3, and SP4. The first and second low-reflectance patterns LP1 and LP2 may be disposed in some or all of the plurality of subpixels SP1, SP2, SP3, and SP4.

Referring to FIG. 9, the first and second low-reflectance patterns LP1 and LP2 according to another embodiment of the present disclosure may extend to both sides in a first direction (or X-axis direction) from each of the data lines DL1, DL2, DL3, and DL4, and may be disposed to overlap the emission areas EA1, EA2, EA3, and EA4.

In the first emission area EA1 of the first subpixel SP1, the first low-reflectance pattern LP1 that extends to the right in a first direction from the first data line DL1 and a second low-reflectance pattern LP2 that extends to the left in the first direction from the second data line DL2 may be disposed. In the second emission area EA2 of the second subpixel SP2, a first low-reflectance pattern LP1 that extends to the right in the first direction from the second data line DL2 and a second low-reflectance pattern LP2 that extends to the left in the first direction from the third data line DL3 may be disposed. In the third emission area EA3 of the third subpixel SP3, a first low-reflectance pattern LP1 that extends to the right in the first direction from the third data line DL3 and a second low-reflectance pattern LP2 that extends to the left in the first direction from the fourth data line DL4 may be disposed. In the fourth emission area EA4 of the fourth subpixel SP4, a first low-reflectance pattern LP1 that extends to the right in the first direction from the fourth data line DL4 may be disposed. For example, one end of the first and second low-reflectance patterns LP1 and LP2 may be integrally connected to each of the data lines DL1, DL2, DL3, and DL4, and another end of the first and second low-reflectance patterns LP1 and LP2 may be electrically floated.

The first and second low-reflectance patterns LP1 and LP2 extending from the first and third data lines DL1 and DL3 may be disposed above each of the emission areas EA1, EA2 and EA3 based on the second direction (or Y-axis direction), and the first and second low-reflectance patterns LP1 and LP2 extending from the second and fourth data lines DL2 and DL4 may be disposed below each of the emission areas EA1, EA2, EA3 and EA4 based on the second direction.

According to another embodiment of the present disclosure, one or more of the first and second low-reflectance patterns LP1 and LP2 may extend from each of the data lines DL1, DL2, DL3, and DL4, and one or more of the first and second low-reflectance patterns LP1 and LP2 may be disposed in each of the emission areas EA1, EA2, EA3 and EA4. The first and second low-reflectance patterns LP1 and LP2 may be disposed only in some of the emission areas EA1, EA2, EA3, and EA4, but embodiments of the present disclosure are not limited thereto.

Referring to FIG. 10, the first and second low-reflectance patterns LP1 and LP2 according to another embodiment of the present disclosure may be disposed on the substrate 111. The first and second low-reflectance patterns LP1 and LP2 may be formed of the same material and in the same layer as the data lines DL1, DL2, DL3, and DL4 and the first power voltage line VDDL on the substrate 111. One end of the first and second low-reflectance patterns LP1 and LP2 may be connected to each of the data lines DL1, DL2, DL3, and DL4, and another end of the first and second low-reflectance patterns LP1 and LP2 may be electrically floated. The first and second low-reflectance patterns LP1 and LP2 may overlap at least one of the color filters CF1, CF3, and CF4, and may overlap the pixel electrode AE of each of the subpixels SP1, SP2, SP3, and SP4. The at least one of the color filters CF1, CF3, and CF4 may be disposed between the pixel electrode AE and the first and second low-reflectance patterns LP1 and LP2.

A lower portion of the first and second low-reflectance patterns LP1 and LP2 may include the low-reflectance material layer LM1 having a lower reflectance than the pixel electrode AE and the common electrode CE. By reflecting or absorbing a portion of externally incident light through the lower portion of the first and second low-reflectance patterns LP1 and LP2 before reaching the pixel electrode AE, the cell reflectance of the emission areas EA1, EA2, EA3 and EA4 may be reduced. Also, the metal layer M1 may be disposed in an upper portion of the first and second low-reflectance patterns LP1 and LP2, and internal reflection of light emitted from the light emitting device ED may be induced through the upper portion of the first and second low-reflectance patterns LP1 and LP2, thereby increasing light extraction efficiency.

According to another embodiment of the present disclosure, it is possible to reduce the reflectance of externally incident light through the first and second low-reflectance patterns LP1 and LP2 that overlap the emission areas EA1, EA2, EA3, and EA4, while maintaining an optimized area of the emission areas EA1, EA2, EA3, and EA4 so that current density is not increased and display quality such as image retention is not degraded. In addition, internal reflection of light emitted from the light emitting device ED may be induced through the first and second low-reflectance patterns LP1 and LP2, thereby increasing light extraction efficiency. Accordingly, it is possible to provide the light emitting display apparatus capable of optimizing the cell reflectance of the emission areas EA1, EA2, EA3, and EA4 suitable for a pol-less structure and improving light efficiency.

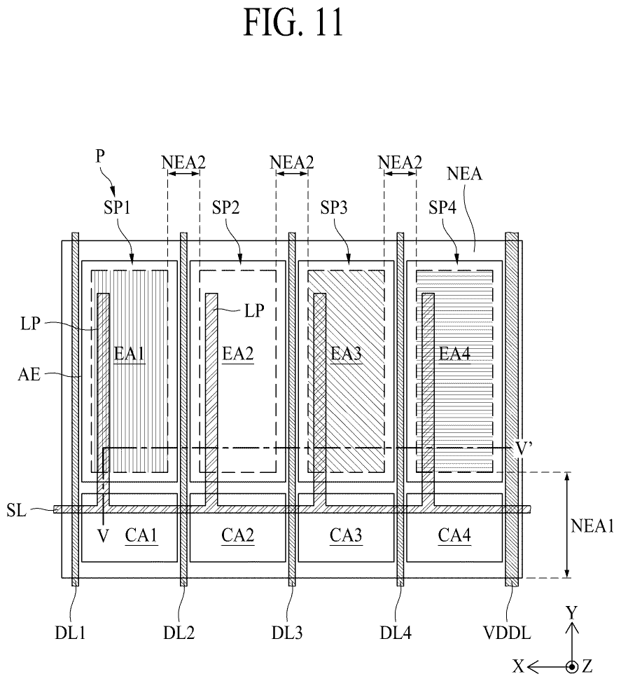

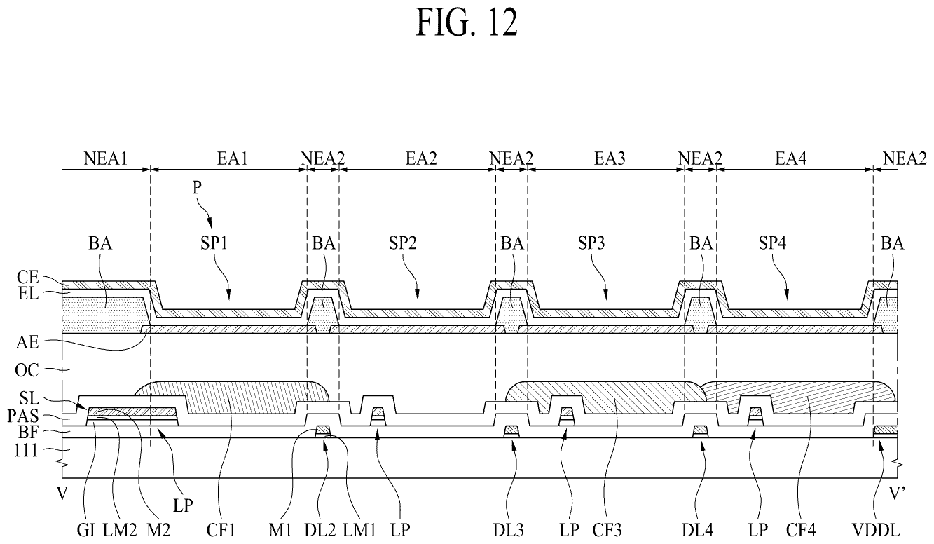

FIG. 11 illustrates a plurality of subpixel in a display panel according to another embodiment of the present disclosure. FIG. 12 is a cross-sectional view taken along line V-V′ of FIG. 11 according to another embodiment of the present disclosure. FIGS. 11 and 12 illustrate another embodiment of the present disclosure in which a low-reflectance pattern configuration is modified in the light emitting display apparatus described with reference to FIGS. 1 to 10. In the following description referring to FIGS. 11 and 12, the same reference numerals will be used for the same components, except for the modified low-reflectance pattern, and their redundant description will be omitted or briefly described.

Referring to FIGS. 11 and 12, the display panel 110 according to another embodiment of the present disclosure may include the low-reflectance pattern LP extending in a second direction (or Y-axis direction) from the scan line SL in at least one of the emission areas EA1, EA2, EA3 and EA4 among the plurality of subpixels SP1, SP2, SP3 and SP4.

Referring to FIG. 11, the low-reflectance pattern LP according to another embodiment of the present disclosure may extend in the second direction (or Y-axis direction) from at least one of the scan lines SL (or gate lines) and may be disposed to overlap the emission areas EA1, EA2, EA3 and EA4.

In the first emission area EA1 of the first subpixel SP1, the low-reflectance pattern LP that extends in the second direction from at least one of the scan lines SL may be disposed. In the second emission area EA2 of the second subpixel SP2, the low-reflectance pattern LP that extends in the second direction from at least one of the scan lines SL may be disposed. In the third emission area EA3 of the third subpixel SP3, the low-reflectance pattern LP that extends in the second direction from at least one of the scan lines SL may be disposed. In the fourth emission area EA4 of the fourth subpixel SP4, the low-reflectance pattern LP that extends in the second direction from at least one of the scan lines SL may be disposed.

The low-reflectance pattern LP disposed in each of the emission areas EA1, EA2, EA3 and EA4 may be disposed on the left side of each of the emission areas EA1, EA2, EA3, and EA4 with respect to a first direction.

According to another embodiment of the present disclosure, one or more of the low-reflectance pattern LP may be disposed in each of the emission areas EA1, EA2, EA3, and EA4, and the low-reflectance pattern LP may be disposed in some or all of the emission areas EA1, EA2, EA3, and EA4, but embodiments of the present disclosure are not limited thereto.

Referring to FIG. 12, the low-reflectance pattern LP according to another embodiment of the present disclosure may be disposed on the buffer layer BF. The low-reflectance pattern LP may be configured with the same material in the same layer as at least one scan line SL on the buffer layer BF. The low-reflectance pattern LP may include a low-reflectance material layer for reducing the reflection of external light. The low-reflectance pattern LP may include the conductive metal layer M2 and the low-reflectance material layer LM2 below the metal layer M2. For example, the metal layer M2 may be configured as a single layer or a multilayer formed of any one of molybdenum Mo, aluminum Al, chromium Cr, tungsten W, gold Au, titanium Ti, nickel Ni, neodymium Nd, and copper Cu, or an alloy thereof, but embodiments of the present disclosure are not limited thereto. The low-reflectance material layer LM2 may be a metal layer having excellent low-reflectance characteristics and may be configured of molybdenum-titanium MoTi or molybdenum Mo or may include a metal oxide or an alloy oxide. For example, the low-reflectance material layer LM2 may include copper oxide CuOx, nickel oxide NiOx, molybdenum oxide MoOx, or tungsten oxide WOx, but embodiments of the present disclosure are not limited thereto. For example, the low-reflectance pattern LP may be a dual-layer structure that includes copper Cu and molybdenum-titanium MoTi, or copper Cu and a metal oxide.

One end of the low-reflectance pattern LP may be connected to at least one scan line SL, and another end of the low-reflectance pattern LP may be electrically floated. The low-reflectance pattern LP may overlap at least one color filter CF1, CF3 and CF4 and may overlap the pixel electrode AE of each subpixel SP1, SP2, SP3 and SP4. The at least one color filter CF1, CF3 and CF4 may be disposed between the pixel electrode AE and the low-reflectance pattern LP.

A lower portion of the low-reflectance pattern LP includes the low-reflectance material layer LM2 having a lower reflectance than the pixel electrode AE and the common electrode CE. By reflecting or absorbing a portion of externally incident light through the lower portion of the low-reflectance pattern LP before reaching the pixel electrode AE, the cell reflectance of the emission areas EA1, EA2, EA3 and EA4 may be reduced. Also, the metal layer M2 may be disposed in the upper portion of the low-reflectance pattern LP, and the light emitted from the light emitting device ED may be internally reflected through the upper portion of the low-reflectance pattern LP, thereby improving light extraction efficiency.

According to another embodiment of the present disclosure, it is possible to reduce the reflectance of externally incident light through the low-reflectance pattern LP that overlap the emission areas EA1, EA2, EA3 and EA4, while maintaining an optimized area of the emission areas EA1, EA2, EA3 and EA4 so that current density is not increased and display quality such as image retention is not degraded. In addition, internal reflection of light emitted from the light emitting device ED may be induced through the low-reflectance pattern LP, thereby increasing light extraction efficiency. Accordingly, it is possible to provide the light emitting display apparatus capable of optimizing the cell reflectance of the emission areas EA1, EA2, EA3 and EA4 suitable for a pol-less structure and improving light efficiency.

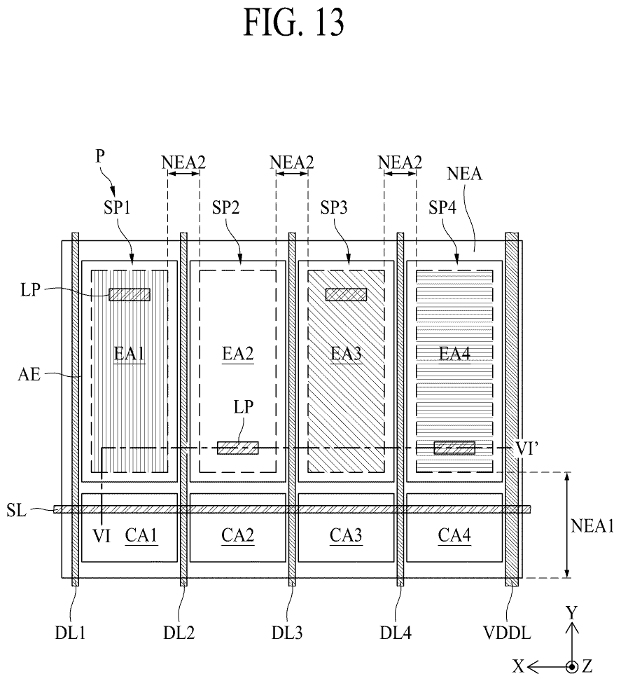

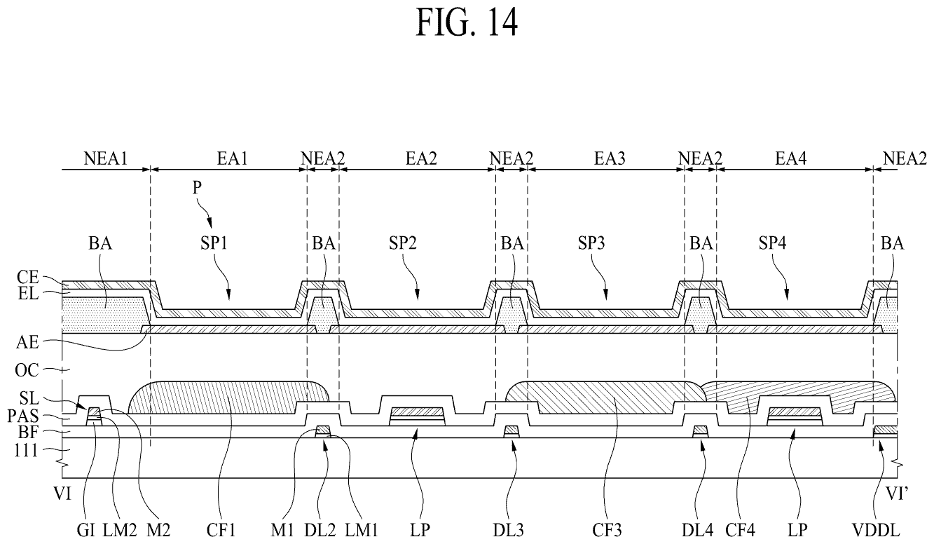

FIG. 13 illustrates a plurality of subpixel in a display panel according to another embodiment of the present disclosure. FIG. 14 is a cross-sectional view taken along line VI-VI′ of FIG. 13 according to another embodiment of the present disclosure. FIGS. 13 and 14 illustrate another embodiment of the present disclosure in which a low-reflectance pattern configuration is modified in the light emitting display apparatus described with reference to FIGS. 1 to 12. In the following description referring to FIGS. 13 and 14, the same reference numerals will be used for the same components, except for the modified low-reflectance pattern, and their redundant description will be omitted or briefly described.

Referring to FIGS. 13 and 14, the display panel 110 according to another embodiment of the present disclosure may include the low-reflectance pattern LP configured as an island pattern extending in a first direction (or X-axis direction) in at least one of the emission areas EA1, EA2, EA3, and EA4 among the plurality of subpixels SP1, SP2, SP3 and SP4. For example, the low-reflectance pattern LP may be configured as an island pattern extending in a second direction (or Y-axis direction). Also, the low-reflectance pattern LP may be disposed in some or all of the plurality of subpixels SP1, SP2, SP3 and SP4.

Referring to FIG. 13, the low-reflectance pattern LP according to another embodiment of the present disclosure may be spaced apart from at least one scan line SL and may be an island pattern extending in the first direction (or X-axis direction) or the second direction (or Y-axis direction) in the emission areas EA1, EA2, EA3 and EA4.

In the first emission area EA1 of the first subpixel SP1, at least one low-reflectance pattern LP that is configured as an island pattern extending in the first direction may be disposed. In the second emission area EA2 of the second subpixel SP2, at least one low-reflectance pattern LP that is configured as an island pattern extending in the first direction may be disposed. In the third emission area EA3 of the third subpixel SP3, at least one low-reflectance pattern LP that is configured as an island pattern extending in the first direction may be disposed. In the fourth emission area EA4 of the fourth subpixel SP4, at least one low-reflectance pattern LP that is configured as an island pattern extending in the first direction may be disposed. For example, both ends of the low-reflectance pattern LP may be electrically floated.

The low-reflectance pattern LP disposed in the first and third emission areas EA1 and EA3 may be disposed above each of the emission areas EA1 and EA3 with respect to the second direction. The low-reflectance pattern LP disposed in the second and fourth emission areas EA2 and EA4 may be disposed below each of the emission areas EA2 and EA4 with respect to the second direction.

According to another embodiment of the present disclosure, one or more of the low-reflectance pattern LP may be disposed in each of the emission areas EA1, EA2, EA3 and EA4, and the low-reflectance pattern LP may be disposed in some or all of the emission areas EA1, EA2, EA3 and EA4, but embodiments of the present disclosure are not limited thereto.

Referring to FIG. 14, the low-reflectance pattern LP according to another embodiment of the present disclosure may be disposed on the buffer layer BF. The low-reflectance pattern LP may be configured with the same material in the same layer as at least one of the scan lines SL on the buffer layer BF. The low-reflectance pattern LP may be configured as an electrically floated island pattern within each of the emission areas EA1, EA2, EA3, and EA4. The low-reflectance pattern LP may overlap at least one of the color filters CF1, CF3, and CF4 and may overlap the pixel electrode AE of each of the subpixels SP1, SP2, SP3, and SP4. The at least one of the color filters CF1, CF3, and CF4 may be disposed between the pixel electrode AE and the low-reflectance pattern LP.

A lower portion of the low-reflectance pattern LP includes the low-reflectance material layer LM2 having a lower reflectance than the pixel electrode AE and the common electrode CE. By reflecting or absorbing a portion of externally incident light through the lower portion of the low-reflectance pattern LP before reaching the pixel electrode AE, the cell reflectance of the emission areas EA1, EA2, EA3, and EA4 may be reduced. Also, the metal layer M2 may be disposed in the upper portion of the low-reflectance pattern LP, and the light emitted from the light emitting device ED may be internally reflected through the upper portion of the low-reflectance pattern LP, thereby improving light extraction efficiency.

According to another embodiment of the present disclosure, it is possible to reduce the reflectance of externally incident light through the low-reflectance pattern LP that overlap the emission areas EA1, EA2, EA3, and EA4, while maintaining an optimized area of the emission areas EA1, EA2, EA3, and EA4 so that current density is not increased and display quality such as image retention is not degraded. In addition, internal reflection of light emitted from the light emitting device ED may be induced through the low-reflectance pattern LP, thereby increasing light extraction efficiency. Accordingly, it is possible to provide the light emitting display apparatus capable of optimizing the cell reflectance of the emission areas EA1, EA2, EA3, and EA4 suitable for a pol-less structure and improving light efficiency.

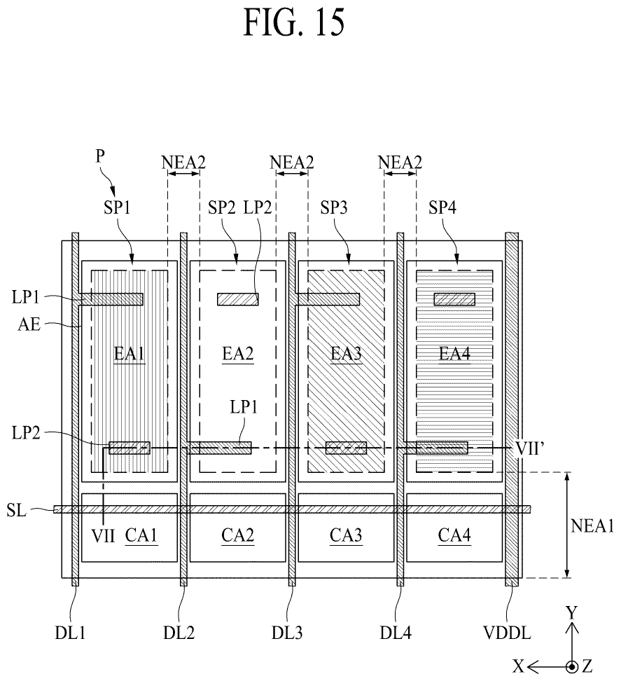

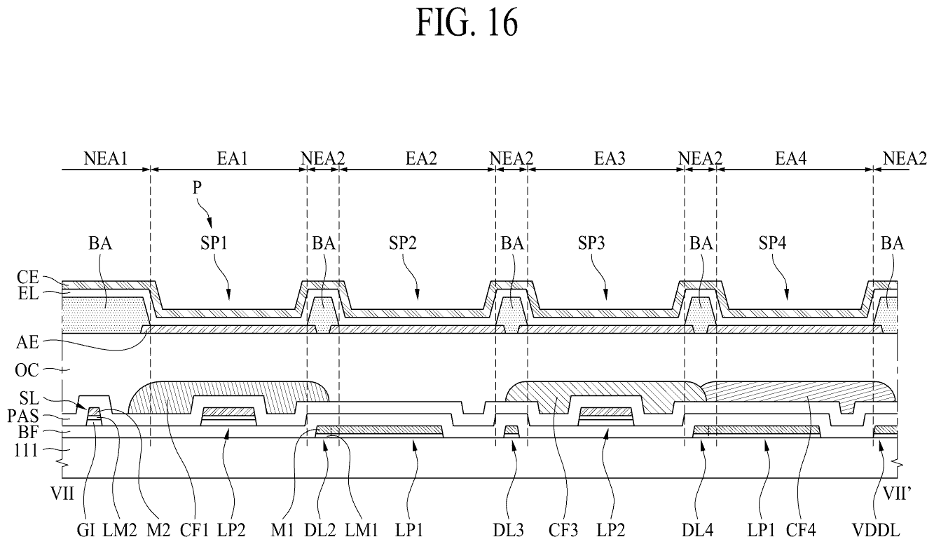

FIG. 15 illustrates a plurality of subpixel in a display panel according to another embodiment of the present disclosure. FIG. 16 is a cross-sectional view taken along line VII-VII′ of FIG. 15 according to another embodiment of the present disclosure. FIGS. 15 and 16 illustrate another embodiment of the present disclosure in which a low-reflectance pattern configuration is modified in the light emitting display apparatus described with reference to FIGS. 1 to 14. In the following description referring to FIGS. 15 and 16, the same reference numerals will be used for the same components, except for the modified low-reflectance pattern, and their redundant description will be omitted or briefly described.

Referring to FIGS. 15 and 16, the display panel 110 according to another embodiment of the present disclosure may include the first and second low-reflectance patterns LP1 and LP2 overlapping at least one of the emission areas EA1, EA2, EA3, and EA4 among the plurality of subpixels SP1, SP2, SP3, and SP4. The first and second low-reflectance patterns LP1 and LP2 may be disposed in some or all of the plurality of subpixels SP1, SP2, SP3, and SP4.

Referring to FIG. 15, the first low-reflectance pattern LP1 according to another embodiment of the present disclosure may extend in a first direction from each of the data lines DL1, DL2, DL3, and DL4 and be disposed to overlap the emission areas EA1, EA2, EA3, and EA4. The second low-reflectance pattern LP2 may be spaced apart from at least one of the scan lines SL and may be an island pattern extending in the first direction in the emission areas EA1, EA2, EA3 and EA4.

In the first emission area EA1 of the first subpixel SP1, the first low-reflectance pattern LP1 that extends in the first direction from the first data line DL1 and the second low-reflectance pattern LP2 that is an island pattern extending in the first direction may be disposed. In the second emission area EA2 of the second subpixel SP2, the first low-reflectance pattern LP1 that extends in the first direction from the second data line DL2 and the second low-reflectance pattern LP2 that is an island pattern extending in the first direction may be disposed. In the third emission area EA3 of the third subpixel SP3, the first low-reflectance pattern LP1 that extends in the first direction from the third data line DL3 and the second low-reflectance pattern LP2 that is an island pattern extending in the first direction may be disposed. In the fourth emission area EA4 of the fourth subpixel SP4, the first low-reflectance pattern LP1 that extends in the first direction from the fourth data line DL4 and the second low-reflectance pattern LP2 that is an island pattern extending in the first direction may be disposed.

The first low-reflectance pattern LP1 that extends from the first and third data lines DL1 and DL3 may be disposed above the first and third emission areas EA1 and EA3 in the second direction. The first low-reflectance pattern LP1 that extends from the second and fourth data lines DL2 and DL4 may be disposed below the second and fourth emission areas EA2 and EA4 in the second direction. Also, the second low-reflectance pattern LP2 disposed in the first and third emission areas EA1 and EA3 may be disposed below the first and third emission areas EA1 and EA3 in the second direction. The second low-reflectance pattern LP2 disposed in the second and fourth emission areas EA2 and EA4 may be disposed above the second and fourth emission areas EA2 and EA4 in the second direction.

According to another embodiment of the present disclosure, one or more of the first low-reflectance pattern LP1 may extend from each of the data lines DL1, DL2, DL3, and DL4, and one or more of the first and second low-reflectance patterns LP1 and LP2 may be disposed in each of the emission areas EA1, EA2, EA3, and EA4. The first and second low-reflectance patterns LP1 and LP2 may be disposed only in some of the emission areas EA1, EA2, EA3, and EA4, but embodiments of the present disclosure are not limited thereto.

Referring to FIG. 16, the first low-reflectance pattern LP1 according to another embodiment of the present disclosure may be disposed on the substrate 111 and the second low-reflectance pattern LP2 may be disposed on the buffer layer BF. The first low-reflectance pattern LP1 may be configured with the same material in the same layer as the data lines DL1, DL2, DL3, and DL4 and the first power voltage line VDDL on the substrate 111, and the second low-reflectance pattern LP2 may be configured with the same material in the same layer as at least one of the scan lines SL on the buffer layer BF. One end of the first low-reflectance pattern LP1 may be connected to each of the data lines DL1, DL2, DL3, and DL4, and another end of the first low-reflectance pattern LP1 may be electrically floated. Also, the second low-reflectance pattern LP2 may be configured as an electrically floated island pattern within each of the emission areas EA1, EA2, EA3, and EA4. The first and second low-reflectance patterns LP1 and LP2 may overlap at least one of the color filters CF1, CF3 and CF4 and may overlap the pixel electrode AE of each of the subpixels SP1, SP2, SP3 and SP4. The at least one of the color filters CF1, CF3 and CF4 may be disposed between the pixel electrode AE and the first and second low-reflectance patterns LP1 and LP2.

A lower portion of the first and second low-reflectance patterns LP1 and LP2 may include the low-reflectance material layers LM1 and LM2 having a lower reflectance than the pixel electrode AE and the common electrode CE, and may reduce the cell reflectance of the emission areas EA1, EA2, EA3, and EA4 by reflecting or absorbing a portion of external light incident from outside through the lower portion of the first and second low-reflectance patterns LP1 and LP2 before reaching the pixel electrode AE. Also, the metal layers M1 and M2 may be disposed in an upper portion of the first and second low-reflectance patterns LP1 and LP2 to induce internal reflection of light emitted from the light emitting device ED through the upper portion of the first and second low-reflectance patterns LP1 and LP2, thereby increasing light extraction efficiency.

According to another embodiment of the present disclosure, it is possible to reduce the reflectance of externally incident light through the first and second low-reflectance patterns LP1 and LP2 that overlap the emission areas EA1, EA2, EA3 and EA4, while maintaining an optimized area of the emission areas EA1, EA2, EA3 and EA4 so that current density is not increased and display quality such as image retention is not degraded. In addition, internal reflection of light emitted from the light emitting device ED may be induced through the first and second low-reflectance patterns LP1 and LP2, thereby increasing light extraction efficiency. Accordingly, it is possible to provide the light emitting display apparatus capable of optimizing the cell reflectance of the emission areas EA1, EA2, EA3 and EA4 suitable for a pol-less structure and improving light efficiency.

A light emitting display apparatus according to one or more embodiments of the present disclosure will be described below.

A light emitting display apparatus according to one or more embodiments of the present disclosure may include a substrate including a plurality of subpixels having an emission area and a non-emission area, a data line and a gate line disposed in the non-emission area on the substrate, intersecting with each other, at least one insulating layer disposed on the data line and the gate line, and a color filter disposed on the at least one insulating layer, corresponding to at least one of the plurality of subpixels, one or more of the plurality of subpixels may include a low-reflectance pattern overlapping the emission area.

According to one or more embodiments of the present disclosure, the low-reflectance pattern may include a low-reflectance material layer.

According to one or more embodiments of the present disclosure, the low-reflectance pattern may be overlapped with the color filter.

According to one or more embodiments of the present disclosure, the low-reflectance pattern may be formed of the same material in the same layer as at least one of the data line and the gate line.

According to one or more embodiments of the present disclosure, the low-reflectance pattern may be connected to or separated from the data line.

According to one or more embodiments of the present disclosure, the low-reflectance pattern may be connected to or separated from the gate line.

According to one or more embodiments of the present disclosure, the low-reflectance pattern may include a metal layer and a low-reflectance material layer below the metal layer.

According to one or more embodiments of the present disclosure, each of the subpixels may include a light emitting device including a pixel electrode, an emission layer and a common electrode, and the emission area may be overlapped with the light emitting device.

According to one or more embodiments of the present disclosure, the low-reflectance pattern may overlap with the pixel electrode, and the color filter may be between the pixel electrode and the low-reflectance pattern.

According to one or more embodiments of the present disclosure, each of the subpixels may include a pixel circuit having at least one thin film transistor and a capacitor, and the non-emission area may include a first non-emission area where the pixel circuit is disposed and a second non-emission area between adjacent subpixels from the plurality of subpixels.

According to one or more embodiments of the present disclosure, the gate line may extend in a first direction in the first non-emission area, and the data line may extend in a second direction intersecting the first direction in the second non-emission area.

According to one or more embodiments of the present disclosure, the low-reflectance pattern may extend from the data line in the first direction and may be disposed to overlap with the emission area.

According to one or more embodiments of the present disclosure, one end of the low-reflectance pattern may be connected to the data line, and another end of the low-reflectance pattern may be electrically floated.

According to one or more embodiments of the present disclosure, the low-reflectance pattern may be spaced apart from the data line and may be an island pattern extending in the first direction or the second direction in the emission area.

According to one or more embodiments of the present disclosure, the low-reflectance pattern may extend from the gate line in the second direction and may be disposed to overlap with the emission area.

According to one or more embodiments of the present disclosure, one end of the low-reflectance pattern may be connected to the data line, and another end of the low-reflectance pattern may be electrically floated.

According to one or more embodiments of the present disclosure, the low-reflectance pattern may be spaced apart from the gate line and may be an island pattern extending in the first direction or the second direction in the emission area.

According to one or more embodiments of the present disclosure, the light emitting display apparatus may further include a bank portion that defines the emission area of each of the subpixels, the bank portion may be disposed between the pixel electrode and the emission layer.

According to one or more embodiments of the present disclosure, the bank portion may include at least one of a light absorbing material and a black material.

According to one or more embodiments of the present disclosure, the light emitting display apparatus may further include a transmittance control film disposed on a rear surface of the substrate.

According to one or more embodiments of the present disclosure, the transmittance control film may include at least one of a transparent film and a light absorbing film.

According to one or more embodiments of the present disclosure, the low-reflectance pattern may include a metal layer and a low-reflectance material layer below the metal layer, the low-reflectance material layer having a lower reflectance than that of each of the pixel electrode and the common electrode.

The above-described feature, structure, and effect of the present disclosure are included in at least one embodiment of the present disclosure, but are not limited to only one embodiment. Furthermore, the feature, structure, and effect described in at least one embodiment of the present disclosure may be implemented through combination or modification of other embodiments by those skilled in the art. Therefore, content associated with the combination and modification should be construed as being within the scope of the present disclosure.

It will be apparent to those skilled in the art that various modifications and variations can be made in the present disclosure without departing from the spirit or scope of the disclosures. Thus, it is intended that the present disclosure covers the modifications and variations of this disclosure provided they come within the scope of the appended claims and their equivalents.

What is claimed is:

1. A light emitting display apparatus comprising:
a substrate including a plurality of subpixels having an emission area and a non-emission area;
a data line and a gate line in the non-emission area on the substrate, the data line and the gate line intersecting with each other;
at least one insulating layer on the data line and the gate line; and
a color filter on the at least one insulating layer, the color filter corresponding to at least one of the plurality of subpixels,
wherein one or more of the plurality of subpixels includes a low-reflectance pattern overlapping the emission area.

2. The light emitting display apparatus of claim 1, wherein the low-reflectance pattern includes a low-reflectance material layer.

3. The light emitting display apparatus of claim 1, wherein the low-reflectance pattern overlaps the color filter.

4. The light emitting display apparatus of claim 1, wherein the low-reflectance pattern includes a same material and is in a same layer as at least one of the data line and the gate line.

5. The light emitting display apparatus of claim 4, wherein the low-reflectance pattern is connected to or separated from the data line.

6. The light emitting display apparatus of claim 4, wherein the low-reflectance pattern is connected to or separated from the gate line.

7. The light emitting display apparatus of claim 1, wherein the low-reflectance pattern includes a metal layer and a low-reflectance material layer below the metal layer.

8. The light emitting display apparatus of claim 1, wherein each of the plurality of subpixels includes a light emitting device including a pixel electrode, an emission layer, and a common electrode, and
wherein the emission area overlaps the light emitting device.

9. The light emitting display apparatus of claim 8, wherein the low-reflectance pattern overlaps the pixel electrode and the color filter is between the pixel electrode and the low-reflectance pattern.

10. The light emitting display apparatus of claim 1, wherein each of the plurality of subpixels includes a pixel circuit having at least one thin film transistor and a capacitor, and
wherein the non-emission area includes a first non-emission area where the pixel circuit is disposed and a second non-emission area between adjacent subpixels from the plurality of subpixels.

11. The light emitting display apparatus of claim 10, wherein the gate line extends in a first direction in the first non-emission area and the data line extends in a second direction intersecting the first direction in the second non-emission area.

12. The light emitting display apparatus of claim 11, wherein the low-reflectance pattern extends from the data line in the first direction and overlaps the emission area.

13. The light emitting display apparatus of claim 12, wherein one end of the low-reflectance pattern is connected to the data line and another end of the low-reflectance pattern is electrically floated.

14. The light emitting display apparatus of claim 11, wherein the low-reflectance pattern is spaced apart from the data line and is an island pattern extending in the first direction or the second direction in the emission area.

15. The light emitting display apparatus of claim 11, wherein the low-reflectance pattern extends from the gate line in the second direction and overlaps the emission area.

16. The light emitting display apparatus of claim 15, wherein one end of the low-reflectance pattern is connected to the data line and another end of the low-reflectance pattern is electrically floated.

17. The light emitting display apparatus of claim 11, wherein the low-reflectance pattern is spaced apart from the gate line and is an island pattern extending in the first direction or the second direction in the emission area.

18. The light emitting display apparatus of claim 8, further comprising:
a bank portion that defines the emission area of each of the plurality of subpixels,
wherein the bank portion is between the pixel electrode and the emission layer.

19. The light emitting display apparatus of claim 18, wherein the bank portion includes at least one of a light absorbing material and a black material.

20. The light emitting display apparatus of claim 8, further comprising:
a transmittance control film on a rear surface of the substrate.

21. The light emitting display apparatus of claim 20, wherein the transmittance control film includes at least one of a transparent film and a light absorbing film.

22. The light emitting display apparatus of claim 8, wherein the low-reflectance pattern includes a metal layer and a low-reflectance material layer below the metal layer, the low-reflectance material layer having a lower reflectance than that of each of the pixel electrode and the common electrode.
